(19) United States
(12) Patent Application Publication
(10) Pub. No.: US 2013/0279112 A1
(43) Pub. Date: Oct. 24, 2013

(54) ELECTRONIC APPARATUS

(71) Applicant: FUJITSU LIMITED, Kawasaki-shi (JP)

(72) Inventors: Huijun Kim, Kawasaki (JP); Takenori Kuwada, Kawasaki (JP); Sonomasa Kobayashi, Kawasaki (JP)

(73) Assignee: FUJITSU LIMITED, Kawasaki-shi (JP)

(21) Appl. No.: 13/853,520

(22) Filed: Mar. 29, 2013

(30) Foreign Application Priority Data
Apr. 23, 2012 (JP) 2012-098228

(51) Int. Cl. H05K 7/20

(52) U.S. Cl. CPC H05K 7/20154; H05K 7/20136
USPC 361/692

(57) ABSTRACT

There is provided an electronic apparatus which includes a heat-generating member, and first and second fans configured to include first and second air outlets, respectively, the first and second fans facing the heat-generating member, wherein each of the first and second air outlets includes a main region and a sub-region separated by respective center lines of the first and second air outlets, when the first and second fans are viewed from a direction perpendicular both to a direction in which the first and second fans are arranged and to a direction in which air passing through the first and second air outlets flows, the volume of air passing through each of the main regions is larger than the volume of air passing through each of the sub-regions, and the main regions are adjacent to each other.

### CROSS-REFERENCE TO RELATED APPLICATION

This application is based upon and claims the benefit of priority of the prior Japanese Patent Application No. 2012-098228, filed on Apr. 23, 2012, the entire contents of which are incorporated herein by reference.

### FIELD

The embodiments discussed herein are related to an electronic apparatus.

### BACKGROUND

There are electronic apparatuses in which a plurality of fans are arranged adjacent to each other for cooling a heat-generating member. Japanese Laid-open Patent Publications No. 2004-247457 and No. 2005-347671 disclose techniques related to such apparatuses.

### SUMMARY

According to an aspect of the invention, an electronic apparatus includes a heat-generating member, and first and second fans configured to include first and second air outlets, respectively, the first and second fans facing the heat-generating member, wherein the first air outlet includes a first main region and a first sub-region separated by a center line of the first air outlet, and the second air outlet includes a second main region and a second sub-region separated by a center line of the second air outlet when the first and second fans are viewed from a direction perpendicular both to a direction in which the first and second fans are arranged and to a direction in which air passing through the first and second air outlets flows, the volume of air passing through the first main region is larger than the volume of air passing through the first sub-region, the volume of air passing through the second main region is larger than the volume of air passing through the second sub-region, and the first and second main regions are adjacent to each other.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a notebook computer according to an embodiment;

FIG. 2 is a perspective view illustrating an internal structure of a housing;

FIG. 3 is an exploded perspective view illustrating a cooling unit and fans in a detached state;

FIG. 4 is an enlarged view of the fans and their surrounding parts;

FIG. 5A is a cross-sectional view taken along line VA-VA of FIG. 4, and FIG. 5B is a cross-sectional view taken along line VB-VB of FIG. 4; and

FIG. 6 illustrates a distribution of volumes of air discharged from the fans.

### DESCRIPTION OF EMBODIMENTS

There is a problem in a conventional arrangement of fans for cooling a heat-generating member. A ventilation opening of a fan includes a region which allows a large volume of air to pass through and a region which allows a small volume of air to pass through. When a plurality of fans are arranged adjacent to each other such that regions which allow a small volume of air to pass through are interposed between regions which allow a large volume of air to pass through, air passing through all ventilation openings of the plurality of fans is uniformly distributed in volume. Generally, the maximum volume of uniformly distributed air is smaller than that of non-uniformly distributed air. Therefore, for example, depending on the shape, material, type, way of heat generation, or position of a heat-generating member, the efficiency of cooling the heat-generating member by blowing non-uniformly distributed air having a larger maximum volume to the heat-generating member may be higher than the efficiency of cooling the heat-generating member by blowing uniformly distributed air to the heat-generating member.

Therefore, it is desired that an electronic apparatus includes a plurality of fans that ensure the maximum volume of air.

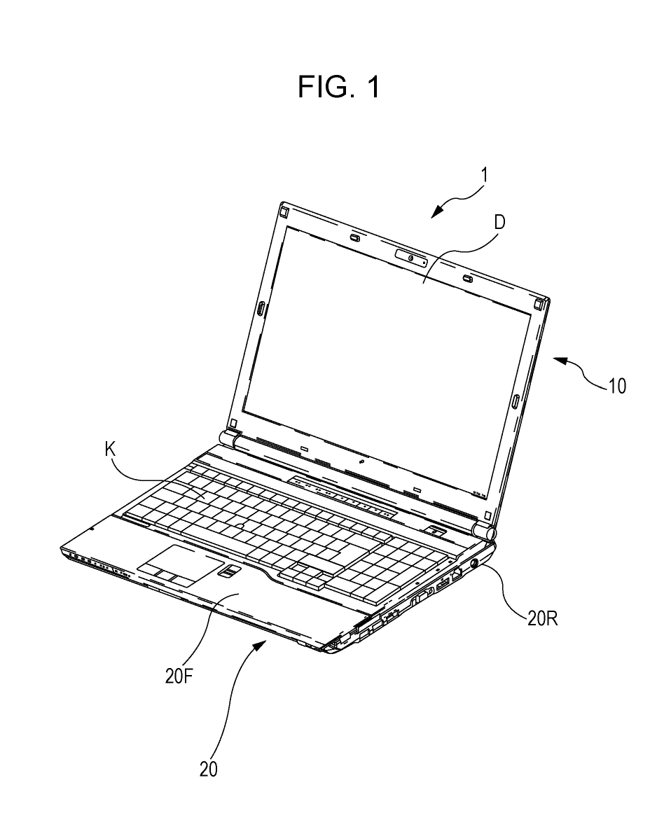

A notebook computer will now be described as an example of an electronic apparatus. FIG. 1 illustrates a notebook computer 1 according to an embodiment. The notebook computer 1 includes housings 10 and 20. The housings 10 and 20 are connected to each other to be openable and closable through a hinge mechanism. The housing 10 includes a display D that displays images. The housing 20 includes a front case 20F and a rear case 20R. The front case 20F includes a keyboard K for operating the notebook computer 1.

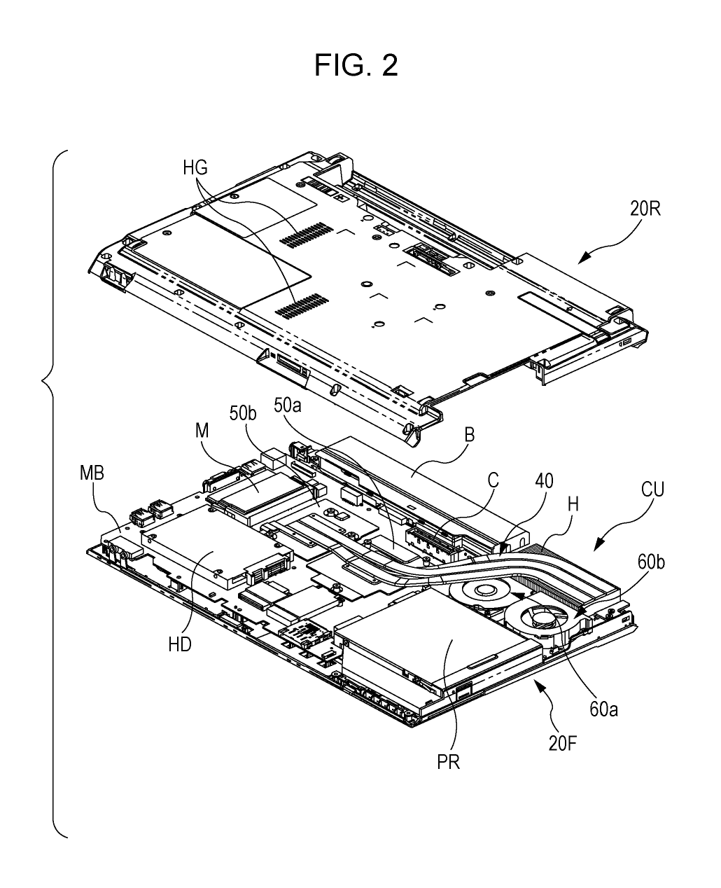

FIG. 2 is a perspective view illustrating an internal structure of the housing 20. The housing 20 includes a motherboard MB including electronic components such as a connector C and a memory M mounted thereon, a battery B, a hard disk HD, a player PR capable of playing a recording medium, and fans 60a and 60b. The fans 60a and 60b are driven by power supplied from the battery B or an external power supply. The housing 20 includes a cooling unit CU that cools a central processing unit (CPU) and a graphics processing unit (GPU).

The cooling unit CU includes a heat pipe unit 40, a single heat sink H, and plates 50a and 50b. The heat sink H is made of metal having high thermal conductivity, such as copper or aluminum alloy. The heat sink H is formed by a plurality of fins connected in parallel. The two fans 60a and 60b are disposed opposite the heat sink H to cool the heat sink H. The heat sink H is an example of a heat-generating member. The rear case 20R is provided with ventilation holes HG through which air passes when the fans 60a and 60b are driven.

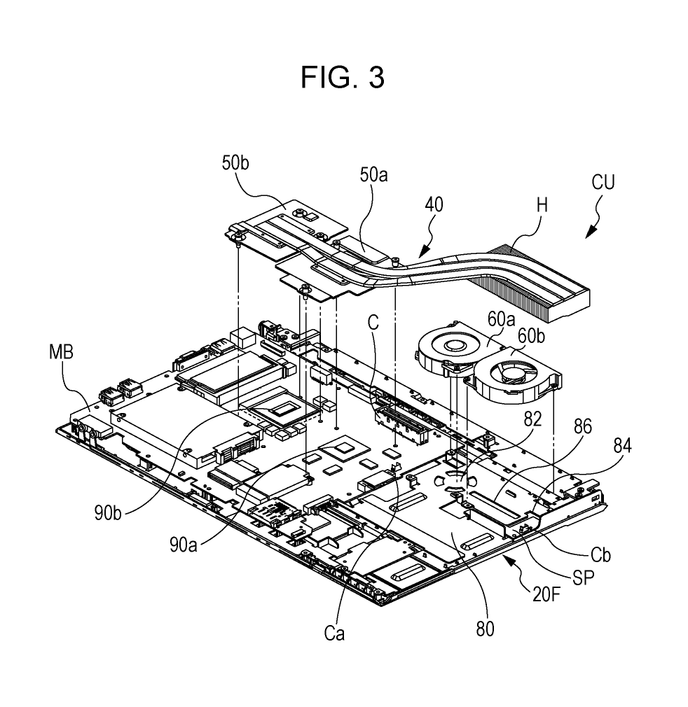

FIG. 3 is an exploded perspective view illustrating the cooling unit CU and the fans 60a and 60b in a detached state. The heat pipe unit 40 is connected at one end thereof to the heat sink H, and connected at the other end thereof to the plates 50a and 50b. The plates 50a and 50b are connected to a GPU 90a and a CPU 90b, respectively. This allows the GPU 90a and the CPU 90b to be cooled. The fans 60a and 60b have a flat shape. The fans 60a and 60b are arranged side by side in the width direction.

The fans 60a and 60b are secured to a metal sheet 80. The metal sheet 80 is provided with ventilation holes 82, 84, and 86 through which air passes when the fans 60a and 60b are driven. The ventilation hole 82 is located opposite the fan 60a. The ventilation hole 86 has a linear shape. A printed circuit board SP is secured to the metal sheet 80 at a location distant from the motherboard MB.

A connector Ca is mounted on the motherboard MB. The connector Ca is electrically connected to the fan 60a through a cable or a flexible printed circuit board. A connector Cb is mounted on the printed circuit board SP. The connector Cb is electrically connected to the fan 60b through a cable or a flexible printed circuit board. The motherboard MB and the printed circuit board SP are electrically connected to each other through a cable or a flexible printed circuit board.

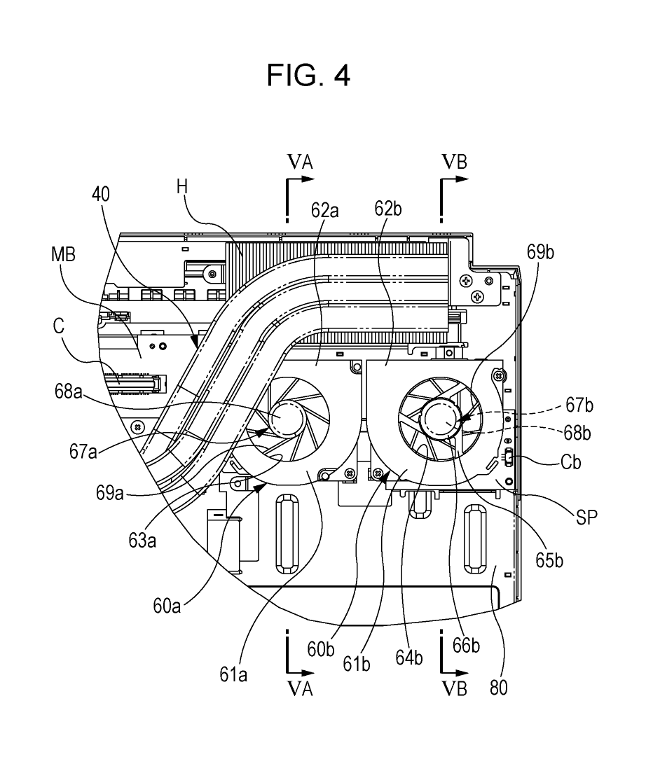

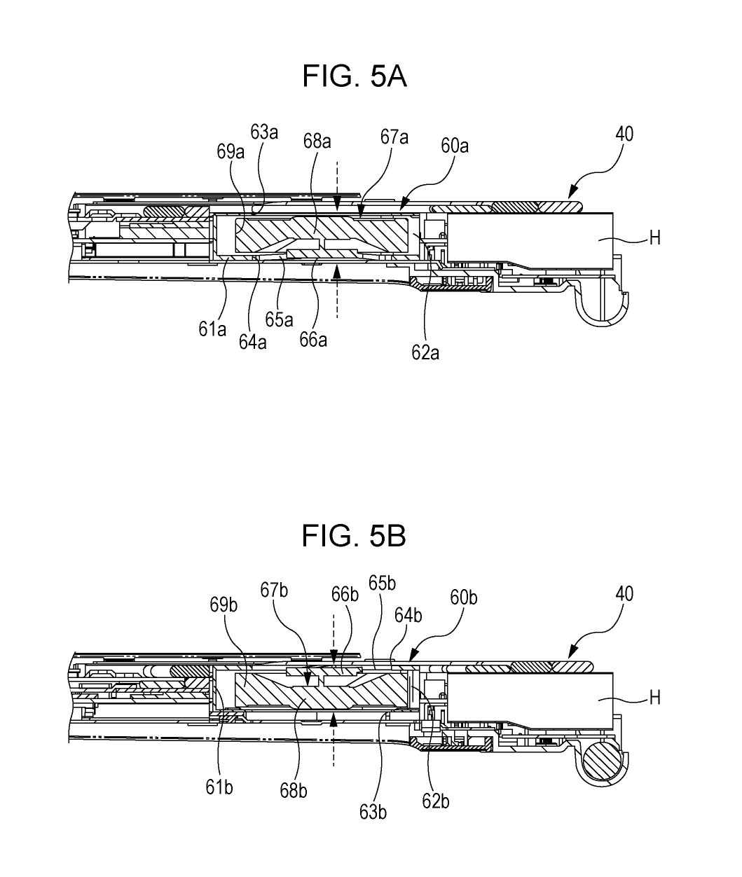

The fans 60a and 60b will now be described. FIG. 4 is an enlarged view of the fans 60a and 60b and their surrounding parts. FIG. 5A is a cross-sectional view taken along line VA-VA of FIG. 4, and FIG. 5B is a cross-sectional view taken along line VB-VB of FIG. 4. The fans 60a and 60b include cases 61a and 61b, respectively. Rotational bodies 67a and 67b are rotatably disposed inside the cases 61a and 61b, respectively. The rotational body 67a includes a rotating shaft 68a and a plurality of blades 69a that extend outward radially from the shaft 68a. Similarly, the rotational body 67b includes a rotating shaft 68b and a plurality of blades 69b that extend outward radially from the shaft 68b. The shafts 68a and 68b include motors for rotating the rotational bodies 67a and 67b, respectively. The shafts 68a and 68b are parallel to each other. In FIG. 5A and FIG. 5B, flows of air drawn into the fans 60a and 60b are indicated by arrows.

As illustrated in FIG. 4 and FIG. 5A, the case 61a is provided with an air outlet 62a and air inlets 63a and 64a. The air inlets 63a and 64a are formed in the upper and lower surfaces, respectively, of the case 61a. The air inlet 64a is adjacent to the metal sheet 80, and the air inlet 63a is remote from the metal sheet 80. The blades 69a are partially exposed from the air inlets 63a and 64a. When the rotational body 67a rotates, air is drawn through the air inlets 63a and 64a into the case 61a, and is discharged from the air outlet 62a by the action of the blades 69a. Air discharged from the air outlet 62a flows in a direction perpendicular to the axial direction of the shaft 68a.

Similarly, as illustrated in FIG. 5B, the case 61b is provided with an air outlet 62b and air inlets 63b and 64b. As illustrated in FIG. 4, the case 61b is provided with three arms 65b extending from the perimeter of the air inlet 64b toward the center. At the center of the air inlet 64b, there is a support 66b connected to the three arms 65b. The support 66b rotatably supports the shaft 68b of the rotational body 67b. Similarly, the case 61a is provided with arms 65a and a support 66a. The fans 60a and 60b are similar or identical in shape, but are disposed to face in opposite directions, upward and downward, in the direction of their axial centers. The air outlets 62a and 62b are positioned to face in the same direction. Specifically, both the air outlets 62a and 62b face the heat sink H. The air outlets 62a and 62b are examples of first and second ventilation openings, respectively. The shafts 68a and 68b are parallel to each other. The fans 60a and 60b are arranged side by side in a direction perpendicular to the shaft 68a.

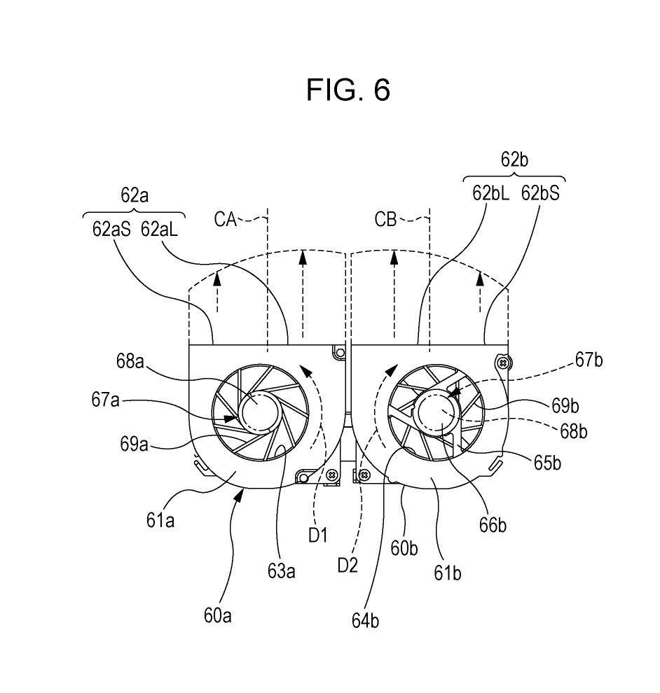

The volume of air discharged from the fans 60a and 60b will now be described. FIG. 6 illustrates a distribution of volumes of air discharged from the fans 60a and 60b. The volumes of air discharged from the air outlets 62a and 62b of the fans 60a and 60b are indicated by dotted lines. The rotational body 67a rotates in a direction D1, and the rotational body 67b rotates in a direction D2 opposite the direction D1. As illustrated in FIG. 6, the direction D1 is a counterclockwise direction and the direction D2 is a clockwise direction. The blades 69a extend outward radially from the shaft 68a in a direction opposite the direction D1. The blades 69a extend in directions of tangents to the perimeter of the shaft 68a. The blades 69b extend outward radially from the shaft 68b in a direction opposite the direction D2. The blades 69b extend in directions of tangents to the perimeter of the shaft 68b. In the air outlet 62a, the direction D1 is directed away from the air outlet 62b. In the air outlet 62b, the direction D2 is directed away from the air outlet 62a.

When the rotational bodies 67a and 67b rotate, air discharged from the air outlets 62a and 62b is distributed as illustrated in FIG. 6. FIG. 6 roughly illustrates the distribution of air volumes. As illustrated in FIG. 6, when the two fans 60a and 60b are viewed from a direction perpendicular both to the direction in which the fans 60a and 60b are arranged and to the direction in which air passing through the air outlets 62a and 62b flows, the air outlet 62a is divided into two regions 62aL and 62aS by an imaginary line CA. The imaginary line CA is parallel to the flow of air passing through the air outlet 62a, and passes through the center of the air outlet 62a. The volume of air passing through the region 62aS is smaller than the volume of air passing through the region 62aL. This is due to both the shape of the blades 69a and the direction of rotation of the rotational body 67a, but is primarily due to the direction of rotation of the rotational body 67a.

Similarly, when the fans 60a and 60b are viewed from the same direction as that described above, the air outlet 62b is divided into two regions 62bL and 62bS by an imaginary line CB. The imaginary line CB is parallel to the flow of air passing through the air outlet 62b, and passes through the center of the air outlet 62b. The volume of air passing through the region 62bS is smaller than the volume of air passing through the region 62bL. The regions 62aL and 62bL are examples of first and second main regions, respectively. The regions 62aS and 62bS are examples of first and second sub-regions, respectively.

The heat sink H is cooled less easily in the center than on the outer sides. In other words, the heat sink H may be efficiently cooled by cooling the center of the heat sink H. In the present embodiment, where the regions 62aL and 62bL which allow a larger volume of air to pass through are arranged adjacent to each other, it is possible to ensure the maximum volume of air passing through the air outlets 62a and 62b. The volume of air passing along or near the boundary between the regions 62aL and 62bL is largest. The regions 62aL and 62bL, which allow a larger volume of air to pass through, are disposed to face substantially the center of the heat sink H. Thus, since a larger volume of air is blown to the center of the heat sink H and the efficiency of cooling the heat sink H is improved, the efficiency of cooling the GPU 90a and the CPU 90b may also be improved.

As illustrated in FIG. 4, the total width of the two fans 60a and 60b is larger than the width of the heat sink H. Therefore, air discharged from the fan 60b through the region 62bS, which allows a smaller volume of air to pass through, flows along a side of the heat sink H. The heat sink H may thus be cooled by effectively using a small volume of air.

As described above, fans of the same shape are used as the fans 60a and 60b. This is less costly than using fans of different shapes.

In the embodiment described above, where the heat sink H is disposed downstream of the fans 60a and 60b in the direction of airflow, the heat sink H is cooled by being exposed to air discharged from the fans 60a and 60b. However, the configuration is not limited to this. For example, a heat-generating member may be disposed upstream of two fans in the direction of airflow such that the heat-generating member is cooled by movement of air drawn into the fans. In this case, again, the two fans are arranged such that, in air inlets of the fans, regions which allow a larger volume of air to pass through are adjacent to each other. This makes it possible to effectively cool the heat-generating member.

A notebook computer has been described as an example of the electronic apparatus in the embodiments above, but the electronic apparatus is not limited to this. For example, the electronic apparatus may be a portable device, such as a tablet computer, a mobile phone, a portable television, an electronic dictionary, a personal digital assistant (PDA), a game machine, a camera, a music player, or a navigation device. The electronic apparatus may be a stationary device, such as a desktop computer, a monitor, a monitor including a computer, a television, an audio device, or a home electrical appliance. The electronic apparatus may be a server for business use.

The heat-generating member is not limited to a heat sink, and may be any component that generates heat. For example, the heat-generating member may be a semiconductor chip, a motor, or a hard disk.

The shape of blades of fans is not limited to that described above. This means that the blades of fans may be of any shape, as long as a plurality of fans are arranged such that regions which allow a larger volume of air to pass through ventilation openings of the fans are adjacent to each other. The two fans may be different in shape or size.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic apparatus comprising:
a heat-generating member; and
first and second fans configured to include first and second air outlets, respectively, the first and second fans facing the heat-generating member,
wherein the first air outlet includes a first main region and a first sub-region separated by a center line of the first air outlet, and the second air outlet includes a second main region and a second sub-region separated by a center line of the second air outlet when the first and second fans are viewed from a direction perpendicular both to a direction in which the first and second fans are arranged and to a direction in which air passing through the first and second air outlets flows, the volume of air passing through the first main region is larger than the volume of air passing through the first sub-region, the volume of air passing through the second main region is larger than the volume of air passing through the second sub-region, and the first and second main regions are adjacent to each other.

2. An electronic apparatus comprising:
a heat-generating member; and
first and second fans configured to include first and second ventilation openings, respectively, the first and second fans facing the heat-generating member,
wherein air is discharged or drawn in from the first and second ventilation openings, the first ventilation opening includes a first main region and a first sub-region separated by a center line of the first ventilation opening, and the second ventilation opening includes a second main region and a second sub-region separated by a center line of the second ventilation opening when the first and second fans are viewed from a direction perpendicular both to a direction in which the first and second fans are arranged and to a direction in which air passing through the first and second ventilation openings, the volume of air passing through the first main region is larger than the volume of air passing through the first sub-region, the volume of air passing through the second main region is larger than the volume of air passing through the second sub-region, and the first and second main regions are adjacent to each other.

3. An electronic apparatus comprising:
a heat-generating member; and
first and second fans configured to include first and second air outlets, respectively, the first and second fans being adjacent to each other,
wherein the first and second fans include respective rotation-axial centers parallel to each other, and are arranged in a direction perpendicular to the rotation-axial centers, the first and second fans rotate in first and second directions, respectively, the first and second fans are opposite each other, the first direction is directed away from the second air outlet in the first air outlet, and the second direction is directed away from the first air outlet in the second air outlet.

4. The electronic apparatus according to claim 3, wherein the first fan includes a first shaft that rotates and a plurality of first blades that extend outward radially from the first shaft in a direction opposite the first direction, and the second fan includes a second shaft that rotates and a plurality of second blades that extend outward radially from the second shaft in a direction opposite the second direction.

5. The electronic apparatus according to claim 1, wherein the first and second fans are identical in shape, and are disposed to face in opposite directions, upward and downward, in a direction of an axial center of the first fan.

6. The electronic apparatus according to claim 2, wherein the first and second fans are identical in shape, and are disposed to face in opposite directions, upward and downward, in a direction of an axial center of the first fan.

7. The electronic apparatus according to claim 3, wherein the first and second fans are identical in shape, and are disposed to face in opposite directions, upward and downward, in a direction of an axial center of the first fan.

8. The electronic apparatus according to claim 4, wherein the first and second fans are identical in shape, and are disposed to face in opposite directions, upward and downward, in a direction of an axial center of the first fan.

9. The electronic apparatus according to claim 1, wherein the heat-generating member is a heat sink thermally connected to a heat-generating component.

10. The electronic apparatus according to claim 2, wherein the heat-generating member is a heat sink thermally connected to a heat-generating component.

11. The electronic apparatus according to claim 3, wherein the heat-generating member is a heat sink thermally connected to a heat-generating component.

12. The electronic apparatus according to claim 4, wherein the heat-generating member is a heat sink thermally connected to a heat-generating component.

13. The electronic apparatus according to claim 5, wherein the heat-generating member is a heat sink thermally connected to a heat-generating component.
